(19) United States
(12) Patent Application Publication
(10) Pub. No.: US 2014/0179093 A1
(43) Pub. Date: Jun. 26, 2014

(54) GATE STRUCTURE FORMATION PROCESSES

(71) Applicant: GLOBALFOUNDRIES, INC., Grand Cayman (KY)

(72) Inventors: Dae-Han CHOI, Loudonville, NY (US); Wontae HWANG, Clifton Park, NY (US); Puneet KHANNA, Clifton Park, NY (US)

(73) Assignee: GLOBALFOUNDRIES, INC., Grand Cayman (KY)

(21) Appl. No.: 13/721,132

(22) Filed: Dec. 20, 2012

(51) Int. Cl. H01L 21/283

(52) U.S. Cl. CPC H01L 21/283
USPC 438/589

(57) ABSTRACT

Gate structures and methods of fabricating gate structures of semiconductor devices are provided. One method includes, for instance: providing a sacrificial layer over a substrate; patterning the sacrificial layer to form a gate opening within the sacrificial layer; providing a gate structure within the gate opening in the sacrificial layer; and removing the sacrificial layer, leaving the gate structure over the substrate. In enhanced aspects, the method includes: forming a reverse sidewall-spacer within the gate opening within the sacrificial layer, and after providing the gate structure, recessing the gate structure within the gate opening, and providing a gate cap within the gate recess in the gate structure.

### FIELD OF THE INVENTION

The present invention relates to semiconductor devices and methods of fabricating semiconductor devices, and more particularly, to gate structures and methods of fabricating gate structures for semiconductor devices.

### BACKGROUND OF THE INVENTION

The gate structure (or gate or transistor gate) is the transistor terminal that modulates channel conductivity. Two principle approaches for forming semiconductor device gate structures are the gate-first and gate-last process approaches.

During fabrication of gate structures for, for instance, complementary metal-oxide-semiconductor (CMOS) technology, gate-first fabrication has traditionally been employed. In a gate-first fabrication approach, a conductor is provided over a gate dielectric, and then patterned (i.e., etched) to form one or more gate structures. After forming the gate structures, source and drain features of the semiconductor devices are provided.

More recently, the gate-last approach (or replacement metal gate (RMG) approach), has been employed. In the gate-last approach, a sacrificial (or dummy) gate material is provided and patterned (i.e., etched) to define one or more sacrificial gates. The one or more sacrificial gates are subsequently replaced with, for instance, a metal gate, after source and drain features of the devices have been formed. The sacrificial gate material holds the position for the subsequent metal gate to be formed. For instance, an amorphous silicon (a-Si) or polysilicon sacrificial gate may be patterned and used during initial processing until high-temperature annealing to activate the source and drain features has been completed. Subsequently, the a-Si or polysilicon may be removed and replaced with the final metal gate.

As noted, in both the gate-first and gate-last approaches, a complicated gate material etch process is required. This process is problematic as critical dimensions continually become smaller.

### BRIEF SUMMARY

The shortcomings of the prior art are overcome and additional advantages are provided through the provision, in one aspect, of a method which includes, for instance: providing a sacrificial layer over a substrate; patterning the sacrificial layer to form a gate opening within the sacrificial layer; providing a gate structure within the gate opening in the sacrificial layer; and removing the sacrificial layer, leaving the gate structure over the substrate.

In another aspect, a method is provided which includes: providing a sacrificial layer over a substrate; patterning the sacrificial layer to form a plurality of gate openings within the sacrificial layer; providing a plurality of gate structures within the plurality of gate openings in the sacrificial layer; and removing the sacrificial layer, leaving the plurality of gate structures over the substrate.

In a further aspect, a semiconductor device is presented which includes a substrate and a plurality of gate structures disposed over the substrate. At least one gate structure of the plurality of gate structures includes a reverse sidewall-spacer and a gate material, wherein the reverse sidewall spacer curves inwardly in a upper region thereof towards the gate material.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a process for fabricating a transistor using a gate-first approach;

FIG. 2 depicts one embodiment of a process for fabricating a transistor using a gate-last approach;

FIG. 3 depicts one embodiment of a process for fabricating, for instance, a transistor using a novel gate structure fabrication approach, in accordance with one or more aspects of the present invention;

FIG. 4A depicts one embodiment of a structure obtained during a gate structure fabrication approach, in accordance with one or more aspects of the present invention;

FIG. 4B depicts the structure of FIG. 4A after patterning one or more gate openings within the sacrificial layer, in accordance with one or more aspects of the present invention;

FIG. 4C depicts the structure of FIG. 4B after provision of reverse sidewall-spacers in the gate openings within the sacrificial layer, in accordance with one or more aspects of the present invention;

FIG. 4D depicts the structure of FIG. 4C after provision of one or more layers of gate structure materials over the sacrificial layer, including within the plurality of gate openings, in accordance with one or more aspects of the present invention;

FIG. 4E depicts the structure of FIG. 4D after planarizing the one or more layers of gate materials down to the sacrificial layer, to define one or more gate structures within the one or more gate openings, in accordance with one or more aspects of the present invention;

FIG. 4F depicts the structure of FIG. 4E after partial recessing of the one or more gate structures, in accordance with one or more aspects of the present invention;

FIG. 4G depicts the structure of FIG. 4F after provision of a gate cap layer over the sacrificial layer, including within the gate recess(es) in the gate structure(s), in accordance with one or more aspects of the present invention; and

FIG. 4H depicts one embodiment of the resultant gate structures obtained after planarizing the gate cap layer down to the sacrificial layer, and then removing the sacrificial layer, leaving the gate structure(s) over the substrate, in accordance with one or more aspects of the present invention.

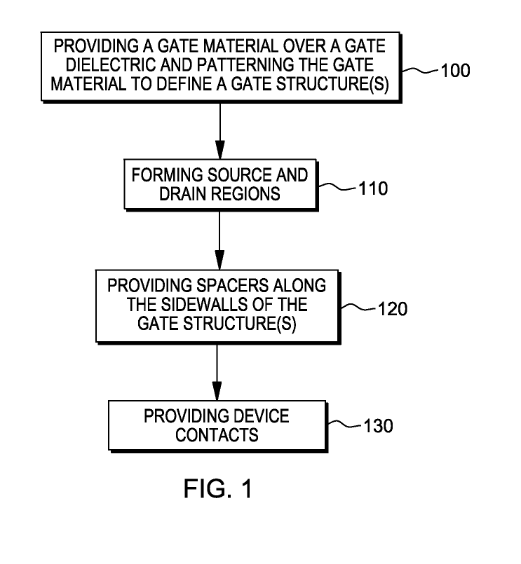

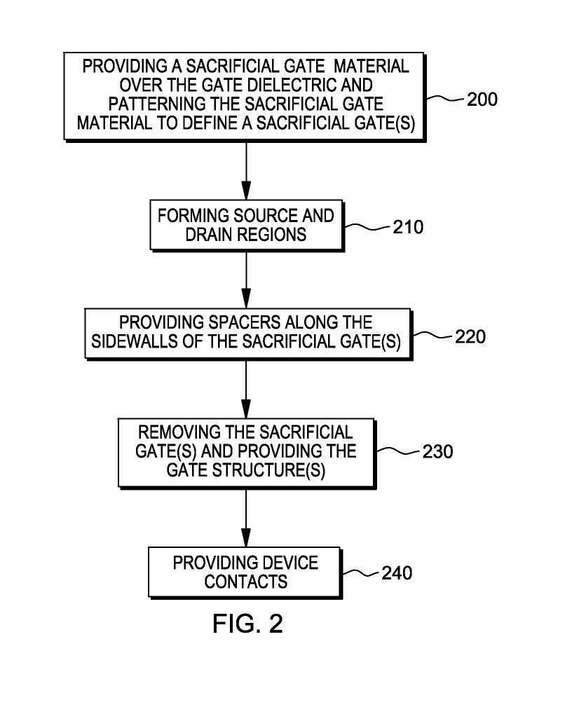

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

As noted above, in a gate-first approach, a gate material is provided over a gate dielectric, and patterned to define one or more gate structures 100. Conventionally, the gate dielectric may include a gate oxide, and the gate material, aluminum or polysilicon. Patterning the gate material involves etching the material, which as semiconductor devices continue to scale smaller and smaller, becomes an ever more complicated etch process. Source and drain regions of the transistors are subsequently formed 110, and spacers along the sidewalls of the gate structures are provided 120. High-temperature annealing may be performed to activate the source and drain regions of the transistor, with the balance of the transistor being formed, in one example, using a traditional CMOS process flow, including providing device contacts to the gate, source, and drain terminals of the transistor 130.

More recently (for instance, in advanced sub-32 nanometer (nm) technologies), gate-last, or replacement metal gate (RMG) processing has been employed, which provides advanced gate structures that include metal gate electrodes. In the gate-last process, a sacrificial gate material is provided over the gate dielectric and patterned to define a sacrificial gate structure 200. In one example, the sacrificial gate structure may include an amorphous silicon (a-Si) or polysilicon gate material, which holds the position for the subsequent metal gate electrode to be formed. After forming the sacrificial gates, source and drain regions are formed 210, and sidewall-spacers are provided over the sidewalls of the sacrificial gates 220. The sacrificial gates remain in place during initial processing until high-temperature annealing is finished, that is, until activation of the source/drain implants has been completed. Subsequently, the sacrificial gates are removed and replaced with replacement metal gates 230. Device contacts are then provided 240 using, for instance, conventional CMOS processing.

Generally stated, disclosed herein are certain novel gate structure formation processes, and gate structures, which provide significant advantages over the above-noted, existing gate structure fabrication processes and structures. Advantageously, the gate structure formation processes disclosed herein may utilize certain gate-first process steps, without performing the complicated gate material etch, as in the conventional gate-first or gate-last process flows. Additionally, as explained herein, common gate profiles may be advantageously obtained, using the gate structure formation processes disclosed herein, for instance, for both N-type field-effect transistors (NFETs), and P-type field-effect transistors (PFETs). Also, since the transistor junctions are formed after gate formation, there is no disturbance to the junctions, as may be the case with a gate-last or replacement metal gate (RMG) fabrication approach.

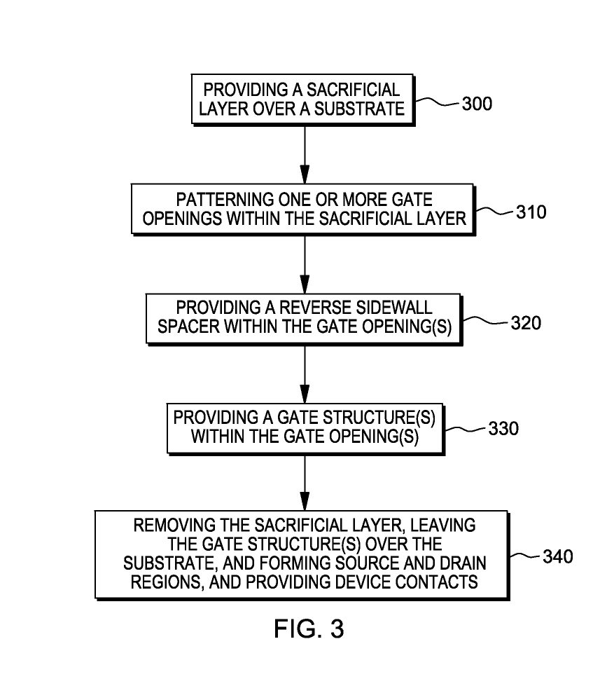

In one aspect, the novel gate structure formation processes disclosed herein may include, for instance: providing a sacrificial layer over a substrate; patterning the sacrificial layer to form a gate opening within the sacrificial layer; providing a gate structure within the gate opening in the sacrificial layer; and removing the sacrificial layer, leaving the gate structure over the substrate. This process is inherent in the more detailed gate structure formation process approach of FIG. 3.

As illustrated in FIG. 3, in one embodiment, gate formation in accordance with one or more aspects of the present invention may include providing a sacrificial layer over a substrate 300, and patterning one or more gate openings within the sacrificial layer 310. If desired, one or more reverse sidewall-spacers may be provided within the gate openings 320 on the sacrificial layer sidewalls defining the gate openings. Further, the gate structures are provided within the gate openings 330. After forming the gate structures, the sacrificial layer is removed, leaving the gate structures over the substrate, and (for instance) standard CMOS processing, including forming source and drain regions, and providing device contacts, may be performed 340.

By way of specific example, the sacrificial layer may be, in one embodiment, selective to silicon and nitride etching processes, and may include, for instance, an oxide layer or an organic layer. The reverse sidewall-spacers provided in the gate openings may include (for example) nitride spacers. Additionally, the resultant gate structures may be recessed within the gate openings to allow for provision of gate caps, such as nitride caps. In one embodiment, the nitride cap may be in contact with the respective sidewall-spacer within the gate opening. By way of example, forming the gate structure may include, for instance, depositing or exposing a gate oxide within the gate opening, followed by depositing and planarizing, for instance, a polysilicon gate material within the gate opening. Alternatively, in another embodiment, forming the gate structure may include, for instance, providing a high-k dielectric layer, one or more work-function metals, and a metal gate, and planarizing the provided high-k dielectric layer, one or more work-function metals, and metal gate, down to the sacrificial layer so that the layer(s) and metal(s) reside within the gate opening. Advantageously, the gate structure formation processes disclosed herein provide similar or identical outer dimensions (or profiles) for both NFET and PFET devices, again without requiring an etch of the gate material.

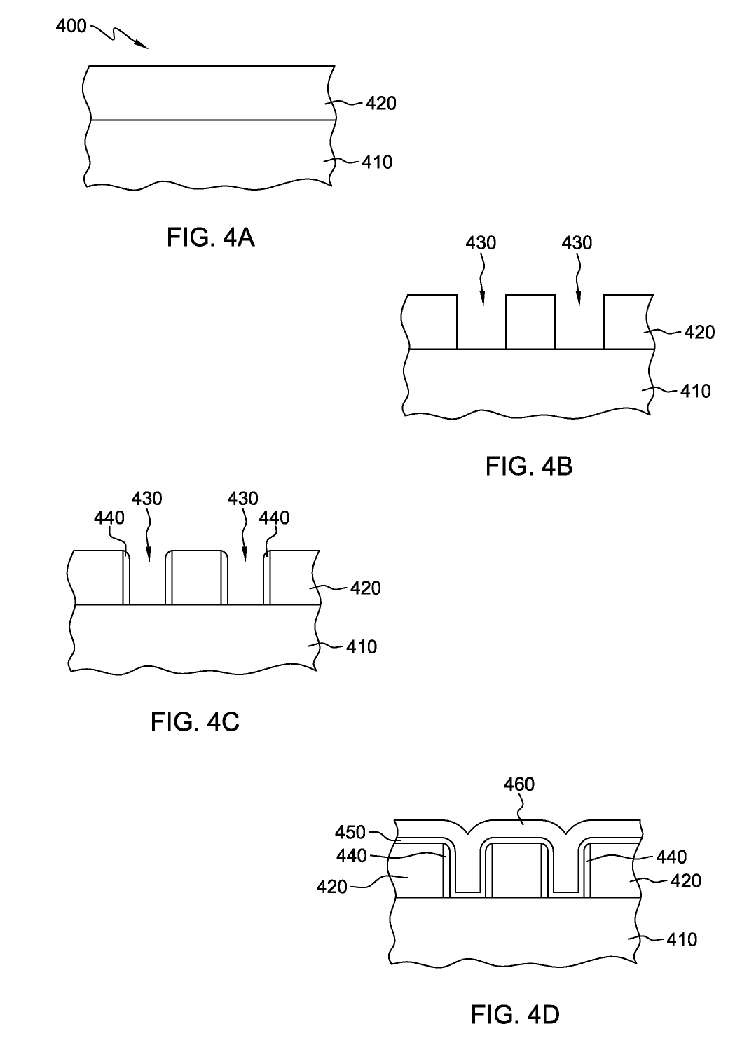

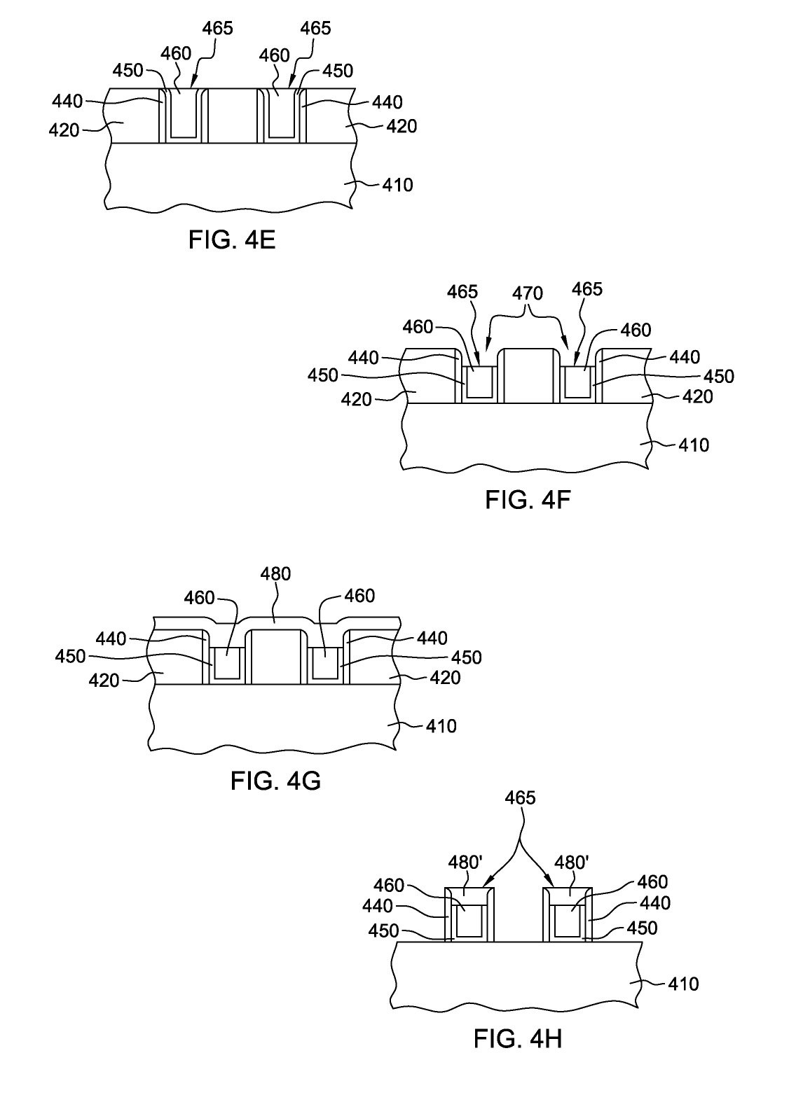

FIGS. 4A-4H depict, by way of example only, one detailed embodiment of a gate structure formation process, and resultant gate structure, in accordance with one or more aspects of the present invention. Note again that these figures are not drawn to scale to facilitate understanding of the invention, and that same reference numbers used throughout different figures designate the same or similar elements.

FIG. 4A is a simplified view of a portion of a device 400, such as a semiconductor device, at an intermediate stage of manufacturing. At the point of fabrication depicted in FIG. 4A, device 400 includes a substrate 410, with a sacrificial layer 420 disposed over substrate 410. In one embodiment, substrate 410 includes silicon, and sacrificial layer 420 may be deposited using conventional deposition processes, such as chemical-vapor deposition (CVD), atomic layer deposition (ALD), physical vapor deposition (PVD), or plasma-enhanced versions of such processes. The sacrificial layer 420 may include a material different from that of the substrate (and the reverse sidewall-spacers discussed below), so that the sacrificial layer may be selectively removed without affecting the substrate (or resultant gate structure(s)). Advantageously, as noted further below, the height of the resultant gate structure(s) may correlate, in one embodiment, to the thickness of sacrificial layer 420 over substrate 410. Thus, the thickness of sacrificial layer 420 may be chosen based on the desired gate structure(s) height. In one example today, the thickness of the sacrificial layer, and thus, the height of the resultant gate structure(s), may be approximately 50 nanometers. By way of further example, the thickness of the sacrificial layer, and thus, the height of the resultant gate structure(s), might be approximately 35-65 nanometers for a planar device, and 50-100 nanometers for FinFET devices.

As depicted in FIG. 4B, sacrificial layer 420 may be patterned with one or more gate openings 430, which extend (in the depicted example) through sacrificial layer 420 to substrate 410. An anisotropic dry-etch process may be employed in patterning sacrificial layer 420 to define gate openings 430. Reactive ion etching or plasma etching may alternatively be employed. In one specific example, reactive ion etching may be performed using fluorine-based chemistry and involve process gases such as tetrafluoromethane (CF₄), trifluoromethane (CHF₃), difluoromethane (CH₂F₂), fluoromethane (CH₃F), octafluorocyclobutane (C₄F₈), hexafluoro-1,3-butadiene (C₄F₆), and oxygen (O₂).

Those skilled in the art will note from the description provided herein that the footprint of a gate opening 430 corresponds to the footprint of the resultant gate electrode formed within that gate opening. As such, by forming gate openings 430 of identical footprint, a plurality of resultant gate electrodes are defined within those gate openings having identical footprints as well. Still further, as noted above, in one implementation, the height of the sacrificial layer 420 determines the height of the gate electrodes, and thus, the height of the resultant gate electrodes may be identical as well, notwithstanding that the composition of the gate electrodes may be different, for instance, as needed for the different gate structures of a semiconductor device having both NFETs and PFETs.

As depicted in FIG. 4C, reverse sidewall-spacers 440 are provided (in one embodiment) within gate openings 430. Reverse sidewall-spacers 440 are thin film layers (or spacers) formed on the sidewalls of sacrificial layer 420 defining gate openings 430. These sidewall-spacers may be formed by deposition or reaction, followed by etching to remove, for instance, all film or spacer material from the horizontal surfaces of the structure depicted, leaving only the reverse sidewall-spacers 440 within gate openings 430. The sidewall-spacers depicted in FIG. 4C, which are reverse in that the upper regions of the spacers curve inwardly, that is, towards the center of the respective gate opening 430, may include a material different from that of sacrificial layer 420 to facilitate subsequent selective etching processes. In one example, reverse sidewall-spacers 440 may be nitride spacers, deposited (for instance) using chemical vapor deposition (CVD) or physical vapor deposition (PVD). In one example, the reverse sidewall-spacers 440 may have a thickness in the range of 3 to 10 nanometers.

As illustrated in FIG. 4D, in one embodiment, the gate formation process includes conformally depositing one or more gate layers or liners 450, for instance, using conventional deposition processes, followed by a gate material 460. As used herein “gate liners” or “gate layers” refer generally to any film or layer which may include part of the gate structure, and includes (for instance) one or more conformally-deposited layers, such as one or more of a gate oxide, a high-k dielectric layer, and/or one or more work-function layers, for example, in the case where the gate material includes a metal. In one example, the gate liners 450 include a high-k dielectric layer with a dielectric constant k greater than about 3.9 (e.g., k=3.9 for SiO₂), and may be deposited by performing a suitable deposition process, such as atomic layer deposition (ALD), chemical vapor deposition (CVD), physical vapor deposition (PVD), or the like. In one specific example, the high-k dielectric layer may include a material such as hafnium oxide (HfO₂), hafnium silicon oxide (HfSiO₃) or hafnium lanthanum oxide (HfLaOx). One or more work-function layers of gate liners 450 may be conformally deposited over the dielectric layer, for example, via a deposition process such as ALD, CVD or PVD. The work-function metal(s) may include, for instance, one or more P-type metals or one or more N-type metals, depending on whether the date structure is to include, for instance, a PFET or an NFET. The work-function layer may include an appropriate refractory metal nitride, for example, those from Groups IVa-VIa in the Periodic Table, including, for example, titanium nitride (TiN), tantalum nitride (TaN), titanium aluminum nitride (TiAlN), tantalum aluminum nitride (TaAlN), niobium nitride (NbN), vanadium nitride (VN), tungsten nitride (WN), and the like. As noted, in one example, the gate material 460 may include a metal, such as, for example, tungsten (W), aluminum (Al), nickel (Ni), cobalt (Co), and titanium (Ti) and may be conformally deposited over the gate liners 450 using processes, such as for instance, atomic layer deposition (ALD) or chemical vapor deposition (CVD).

As illustrated in FIG. 4E, a non-selective chemical-mechanical polish may be employed to polish away excess gate material 460 and excess gate liners 450, with the chemical-mechanical polishing terminating at sacrificial layer 420, resulting (as noted) in the height of gate structures 465 being substantially equal to the thickness of sacrificial layer 420, as illustrated in FIG. 4E. Thus, in accordance with this approach, by selecting the thickness of the sacrificial layer, it is possible to accurately select the height of the gate structures. Similarly, by identically patterning gate openings 430 (see FIGS. 4B & 4C), it is possible to form identically-dimensioned gate structures over substrate 410, notwithstanding that different gate structures may have different gate liners, for instance, dependent on whether the gate structure is for an NFET or PFET. This is advantageously accomplished using the gate structure formation process disclosed herein, without requiring any complicated patterning of the gate material, as in the gate-first or gate-last approaches.

FIGS. 4F & 4G depict a further process step, wherein gate structures 465 are recessed, and in particular, the gate liner(s) 450 and gate material 460 are recessed, to allow for formation of a gate cap 480′ (see FIG. 4H) for the gate structure 465. In one example the gate structures 465 may be recessed 20-50% of their height using, for instance, an anisotropic dry-etching process. For instance, if the gate height is 50 nanometers, then the gate structures 465 may be recessed, for instance, 10-25 nanometers. Gate caps 480′ (FIG. 4H) may be formed by conformally depositing within the gate recesses 470 (see FIG. 4F) and over the recessed gate structures 465, a capping material 480 (see FIG. 4G), such as a nitride material. The capping layer 480 is then polished back using, for instance, chemical-mechanical polishing, again stopping on the sacrificial layer 420 to provide the desired gate caps 480′. Subsequently, sacrificial layer 420 may be removed using conventional selective etch processing for (for example) an oxide or organic material, leaving the gate structures 465 over substrate 410.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method comprising:
forming a transistor using a gate-first approach, the forming comprising:
providing a sacrificial layer over a substrate;
patterning the sacrificial layer to form a gate opening within the sacrificial layer;
providing a gate structure within the gate opening in the sacrificial layer, the gate structure comprising one or more refractory material liners and a non-refractory gate fill material;
removing the sacrificial layer, leaving the gate structure over the substrate; and
after the removing, establishing a source region and a drain region of the transistor, at least in part, within the substrate, the establishing comprising annealing the source region and the drain region, wherein the one or more refractory material liners of the gate structure are selected to inhibit heat damage to the non-refractory gate fill material during the annealing.

2. The method of claim 1, wherein the sacrificial layer is selective to silicon and nitride etching processes.

3. The method of claim 1, wherein the sacrificial layer comprises one of an oxide layer or an organic layer.

4. The method of claim 1, further comprising forming a reverse sidewall-spacer in the gate opening within the sacrificial layer.

5. The method of claim 4, wherein the reverse sidewall-spacer comprises a nitride spacer formed within the gate opening in the sacrificial layer.

6. The method of claim 4, further comprising recessing the gate structure within the gate opening, and providing a gate cap within the recess in the gate structure.

7. The method of claim 6, wherein the gate cap comprises a nitride cap and the reverse sidewall spacer comprises a nitride spacer.

8. The method of claim 1, wherein forming the gate structure comprises providing a gate dielectric within or exposed by the gate opening, providing a gate material over the gate dielectric, and planarizing the gate material to form the gate structure.

9. The method of claim 8, wherein the gate dielectric comprises a high-k dielectric layer, and the gate material comprises a metal gate, and Wherein the forming the gate structure further comprises providing at least one work-function metal layer between the high-k dielectric layer and the metal gate.

10. A method comprising:
forming a plurality of transistors using a gate-first approach, the forming comprising:
providing a sacrificial layer over a substrate;
patterning the sacrificial layer to form a plurality of gate openings within the sacrificial layer;
providing a plurality of gate structures within the plurality of gate openings in the sacrificial layer, at least one gate structure of the plurality of gate structures comprising one or more refractory material liners and a non-refractory gate fill material;
removing the sacrificial layer, leaving the plurality of gate structures over the substrate; and
after the removing, establishing source regions and drain regions within, at least in part, the substrate for the plurality of transistors, the establishing comprising annealing the source regions and the drain regions, wherein the one or more refractory material liners of the at least one gate structure are selected to inhibit heat damage to the non-refractory gate fill material during the annealing.

11. The method of claim 10, wherein the sacrificial layer comprises a material different from the substrate, and wherein the sacrificial layer is selective to silicon and nitride etching processes.

12. The method of claim 10, wherein the sacrificial layer comprises one of an oxide or an organic material.

13. The method of claim 10, wherein a height of at least one gate structure of the plurality of gate structures substantially equals a height of the sacrificial layer over the substrate.

14. The method of claim 10, further comprising forming reverse sidewall-spacers in the plurality of gate openings in the sacrificial layer.

15. The method of claim 14, wherein the reverse sidewall-spacers comprise nitride spacers formed within the plurality of gate openings in the sacrificial layer.

16. The method of claim 10, wherein forming a gate structure of the plurality of gate structures comprises providing a gate dielectric within or exposed by the gate opening to accommodate the gate structure, providing a gate material over the gate dielectric, and planarizing the gate material to form the gate structure.

17. The method of claim 16, wherein the gate dielectric comprises a high-k dielectric layer, and the gate material comprises a metal gate, and wherein the forming the gate structure further comprises providing at least one work-function metal between the high-k dielectric layer and the metal gate.

18. The method of claim 10, further comprising recessing the plurality of gate structures within the plurality of gate openings, and providing gate caps within the gate recesses in the plurality of gate structures.

19. The method of claim 18, wherein the gate caps comprise nitride caps.

20. The method of claim 10, wherein at least two gate openings of the plurality of gate openings have substantially identical dimensions, one gate opening of the at least two gate openings accommodating one gate structure for an N-type transistor, and another gate opening of the at least two gate openings accommodating another gate structure for a P-type transistor, wherein the one gate structure and the another gate structure comprise at least one different material or at least one different layer, and comprise substantially identical outer dimensions.

21-22. (canceled)

23. The method of claim 1, wherein the removing comprises completely removing the sacrificial layer to expose the gate structure and the substrate.

24. The method of claim 10, wherein the removing comprises completely removing the sacrificial layer to expose the plurality of gate structures and the substrate.
